(19) United States
(12) Patent Application Publication
(10) Pub. No.: US 2011/0017260 A1
(43) Pub. Date: Jan. 27, 2011

(54) SOLAR CELL MODULE

(75) Inventors: Satoru Ogasahara, Ichinomiya-shi (JP); Yuji Kitamura, Gifu-shi (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/841,527

(22) Filed: Jul. 22, 2010

(30) Foreign Application Priority Data
Jul. 24, 2009 (JP) 2009-173147
Sep. 29, 2009 (JP) 2009-224377

(51) Int. Cl. H01L 31/042

(52) U.S. Cl. 136/244

(57) ABSTRACT

A solar cell module is provided comprising a power generation unit having a plurality of thin film solar battery cells, an electricity extraction unit having a front side electrode which is connected to a thin film solar battery cell positioned at an end of the power generation unit, a tab electrode formed over the electricity extraction unit and configured to extract electricity generated by the power generation unit, a solder joint which joins the front side electrode and the tab electrode, and a tab line provided to extract electricity from the tab electrode and joined to the tab electrode by solder at a position overlapping the solder joint in a plan view.

### CROSS-REFERENCE TO RELATED APPLICATIONS

The entire disclosure of Japanese Patent Application No. 2009-173147 filed on Jul. 24, 2009 and Japanese Patent Application No. 2009-224377 filed on Sep. 29, 2009, including specification, claims, drawings, and abstract, is incorporated herein by reference in its entirety.

### BACKGROUND

1. Technical Field

The present invention relates to a solar cell module, and in particular, to a solar cell module having an extraction electrode for extracting electricity generated by a power generation unit, and an extraction line joined to the extraction electrode by a fusing section for extracting electricity from the extraction electrode.

2. Background Art

Conventionally, a solar cell module is known which comprises an extraction electrode for extracting electricity generated by a power generation unit, and an extraction line joined to the extraction electrode by a fusing section for extracting electricity from the extraction electrode.

A solar cell module in the related art will now be described with reference to FIGS. 8 and 9. FIG. 8 is a schematic diagram showing a thin film solar battery cell of a solar cell module. FIG. 9 is an enlarged cross sectional diagram of the solar cell module shown in FIG. 8, along a line A-A.

In a solar cell module 101, a plurality of thin film solar battery cells 120 are formed over a substrate 102. The thin film solar battery cell 120 is formed by a layered structure in which a front side electrode 103, a photoelectric conversion unit 104, and a backside electrode 105 are layered in this order from the side of the substrate 102. Adjacent thin film solar battery cells 120 and 120 are electrically connected in series by the front side electrode 103, to form a group of thin film solar battery cells 140. Electric power generated by the group of thin film solar battery cells 140 is extracted from a bus region 130 provided at an end section of a connection of the plurality of thin film solar battery cells 120.

In addition, the plurality of thin film solar battery cells 120 electrically connected in series are electrically separated by a slit (separation groove) S101 along the direction of the series connection of the plurality of thin film solar battery cells 120. With this configuration, the group of thin film solar battery cells 140 is ultimately connected in parallel, and the solar cell module 101 is formed.

Moreover, in order to extract electricity generated in the thin film solar battery cell, an electricity extraction unit is provided which comprises a connecting section connected to a thin film solar battery cell positioned at an end of the power generation unit. An extraction electrode is placed above the connecting section of the electricity extraction unit, and a lower surface of the extraction electrode and the connecting section are joined via a first solder joint. In addition, an extraction line for extracting the electricity from the extraction electrode is joined to an upper surface of the extraction electrode by a second solder joint. The extraction line is joined to the extraction electrode via the second solder joint by heating the extraction line and the extraction electrode in a state where the extraction electrode is joined to the connecting section by the first solder joint. The thin film solar battery cell, the electricity extraction unit, the extraction electrode, and the extraction line formed over the glass substrate are sealed between the glass substrate and a back sheet by a sealing member.

Prevention of detachment of the extraction line from the extraction electrode is an important factor in maintaining the reliability of the solar cell module. In addition, conventionally, an improvement in conversion efficiency is desired in the solar cell module in order to increase an amount of power generation, and improvements have been made.

### SUMMARY

According to one aspect of the present invention, there is provided a solar cell module comprising a substrate, a power generation unit comprising a plurality of thin film solar battery cells having a front side electrode formed over the substrate, a photoelectric conversion layer formed over the front side electrode, and a backside electrode formed over the photoelectric conversion layer, an electricity extraction unit comprising a connecting section connected to a thin film solar battery cell positioned at an end of the power generation unit, an extraction electrode formed over the electricity extraction unit and configured to extract electricity generated by the power generation unit, a first fusing section which joins the connecting section and the extraction electrode, and an extraction line provided to extract electricity from the extraction electrode and joined to the extraction electrode by a second fusing section at a position overlapping the first fusing section in a plan view.

According to another aspect of the present invention, there is provided a solar cell module comprising a substrate which is light transmissive, a plurality of thin film solar battery cells provided over the substrate and connected to each other in a first direction, an extraction electrode provided over a first surface of the plurality of thin film solar battery cells and configured to collect electric power, and an extraction line connected to the extraction electrode over the first surface of the thin film solar battery cell and configured to extract the electric power from the extraction electrode to the outside, wherein the plurality of thin film solar battery cells are divided by a slit extending in a second direction crossing the first direction, and the extraction electrode is placed to overlap the slit.

### BRIEF DESCRIPTION OF THE DRAWINGS

Preferred embodiments of the present invention will be described in further detail based on the following drawings, wherein:

FIG. 1 is a plan view of an integrated solar cell module in a first preferred embodiment of the present invention, viewed from the backside (side opposite to the light incidence side);

FIG. 2 is a cross sectional diagram along a line 100-100 in FIG. 1;

FIG. 3 is a cross sectional diagram along a line 200-200 in FIG. 1;

FIG. 4 is a cross sectional diagram along a line 300-300 in FIG. 1;

FIG. 5 is a top view of a solar cell module according to a second preferred embodiment of the present invention;

FIG. 6 is a cross sectional diagram along an A′-A′ cross section of the solar cell module of the second preferred embodiment of the present invention shown in FIG. 5;

FIG. 7 is a cross sectional diagram along a B-B cross section of the solar cell module according to the second preferred embodiment of the present invention shown in FIG. 5;

FIG. 8 is a top view of a solar cell module in related art; and

FIG. 9 is a cross sectional diagram along an A-A cross section of the solar cell module shown in FIG. 8.

### DESCRIPTION OF EMBODIMENT

### First Preferred Embodiment

A first preferred embodiment of the present invention will now be described with reference to the drawings.

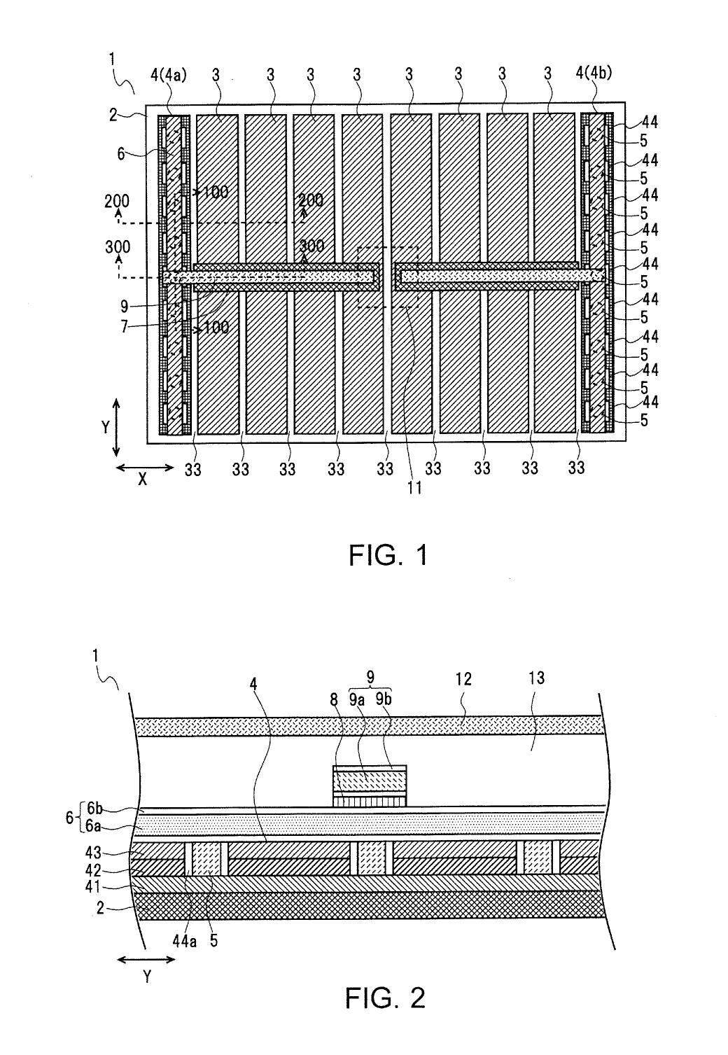

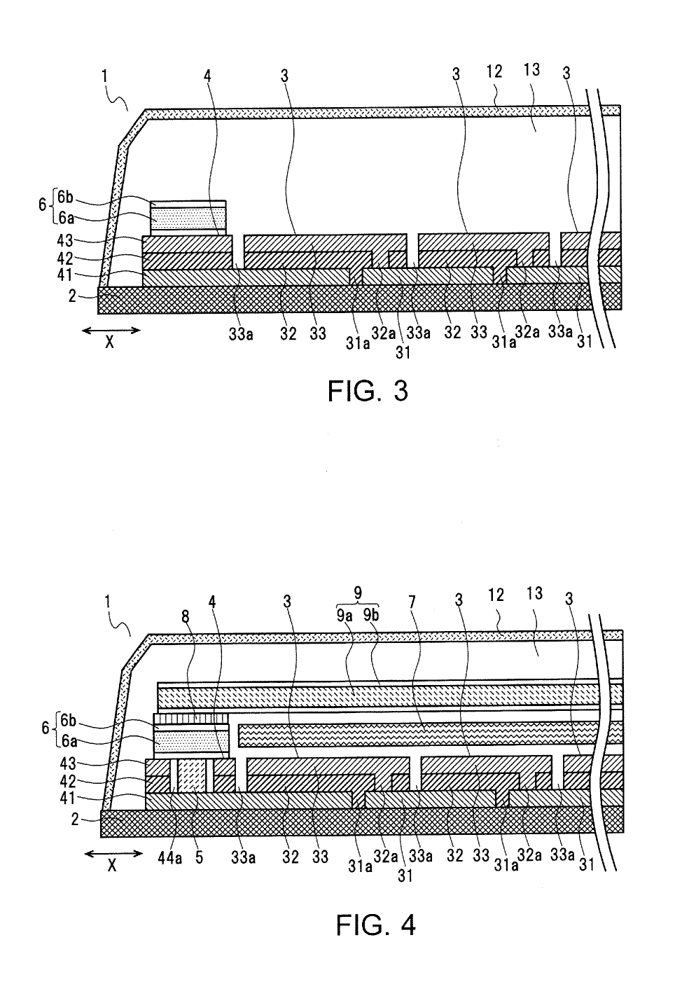

A structure of an integrated solar cell module 1 in a first preferred embodiment of the present invention will now be described with reference to FIGS. 1-4.

As shown in FIGS. 1-4, the integrated solar cell module 1 in the present embodiment comprises a substrate 2 provided on a side of incidence of light (refer to FIGS. 2-4), a plurality of thin film solar battery cells 3 formed over a surface of the substrate 2 and connected in series along an X direction, an electricity extraction unit 4 formed over a surface of the substrate 2 and connected to thin film solar battery cells 3 placed at both ends in the X direction, and a pair of tab electrodes 6 connected to the electricity extraction unit 4 by a solder joint 5 and configured to extract the electricity generated by the thin film solar battery cell 3 to the outside. The solar cell module 1 further comprises an insulating tape 7 provided to cover an upper surface of the thin film solar battery cell 3, and a pair of tab lines 9 joined to the pair of tab electrode 6 via a solder joint 8. In addition, on the side of the backside of the solar cell module 1, a back sheet 12 comprising a layered structure of PET (Polyethylene Terephthalate) and a metal is placed, and the side is sealed by a sealing member 13 made of EVA (Ethylene-Vinyl Acetate). Alternatively, as the sealing member 13, in place of EVA, it is also possible to use an ethylene-based resin such as EEA, PVB, silicon, urethane, acryl, or epoxy resin. The tab line 9 extends from an opening formed in the back sheet 12, and a terminal box 11 (refer to FIG. 1) for mounting a power extraction line (not shown) is provided at an end of the extending tab line 9. In the plan view, each thin film solar battery cell 3 is formed in a rectangular shape having a long side along the Y direction perpendicular to the X direction. The electricity extraction unit 4 is formed to extend along the Y direction in the plan view. In FIG. 1, the sealing member 13 and the back sheet 12 are not shown.

The substrate 2 has an insulating surface and is made of glass having a light transmitting characteristic. The substrate 2 has a thickness of greater than or equal to approximately 1 mm and less than or equal to approximately 5 mm. The plurality of thin film solar battery cells 3 are formed on the backside opposite to the light incidence side of the substrate 2.

The thin film solar battery cell 3 comprises a front side electrode 31 formed over a surface of the substrate 2, a photoelectric conversion unit 32 formed over a surface of the front side electrode 31, and a backside electrode 33 formed over a surface of the photoelectric conversion unit 32. The photoelectric conversion unit 32 is an example of a “photoelectric conversion layer” of the present invention.

The front side electrode 31 has a thickness of approximately 800 nm, and is made of a transparent conductive oxide (TCO) such as tin oxide (SnO₂), zinc oxide (ZnO), indium tin oxide (ITO), titanium oxide (TiO₂), and zinc tin oxide (Zn₂SnO₄) which is conductive and light transmissive. Front side electrodes 31 of thin film solar battery cells 3 adjacent to each other are separated by a groove section 31a.

The photoelectric conversion unit 32 is made of a pin-type amorphous silicon-based semiconductor. The photoelectric conversion unit 32 made of the pin-type amorphous silicon-based semiconductor comprises a p-type hydrogenated amorphous silicon carbide (a-SiC:H) layer having a thickness of greater than or equal to approximately 10 nm and less than or equal to approximately 20 nm, an i-type hydrogenated amorphous silicon (a-Si:H) layer having a thickness of greater than or equal to approximately 250 nm and less than or equal to approximately 350 nm, and an n-type hydrogenated amorphous silicon layer having a thickness of greater than or equal to approximately 20 nm and less than or equal to approximately 30 nm. In addition, photoelectric conversion units 32 of thin film solar battery cells 3 adjacent to each other are separated by a groove section 32a.

The backside electrode 33 is formed over an upper surface of the photoelectric conversion unit 32. The backside electrode 33 has a thickness of greater than or equal to approximately 200 nm and less than or equal to 400 nm, and is made of a metal material having silver (Ag) as a primary constituent. In addition, the backside electrode 33 has a function to reflect light incident from a side of a lower surface of the substrate 2 and reaching the backside electrode 33, so that the light is again incident to the photoelectric conversion unit 32. The backside electrodes 33 of thin film solar battery cells 3 adjacent to each other are separated by a groove section 33a formed in a region corresponding to the groove section 32a. The groove section 33a separates the photoelectric conversion unit 32, and is formed at the surface of the front side electrode 31. Alternatively, it is also possible to form a layer of TCO (for example, ZnO or ITO) having a thickness of approximately 100 nm between the photoelectric conversion unit 32 and the backside electrode 33 (between a semiconductor layer 42 and a backside electrode 43 to be described later).

The front side electrode 31 of one thin film solar battery cell 3 of two adjacent thin film solar battery cells 3 is connected to the backside electrode 33 of the other thin film solar battery cell 3 of the two adjacent thin film solar battery cells 3, to form a plurality of thin film solar battery cells 3 of the integrated type which are connected in series. The plurality of thin film solar battery cells 3 form the “power generation unit” of the present invention.

The electricity extraction unit 4 comprises an electricity extraction unit 4a provided at one end in the X direction which forms a positive pole of the solar cell module 1 and an electricity extraction unit 4b provided at the other end in the X direction which forms a negative pole of the solar cell module 1. The electricity extraction unit 4 (electricity extraction units 4a and 4b) comprises a front side electrode 41 formed over a surface of the substrate 2, a semiconductor layer 42 formed over a surface of the front side electrode 41, and a backside electrode 43 formed over a surface of the semiconductor layer 42. Structures, such as the materials and thicknesses, of the front side electrode 41, the semiconductor layer 42, and the backside electrode 43 are similar to those for the front side electrode 31, the photoelectric conversion unit 32, and the backside electrode 33 of the thin film solar battery cell 3. In addition, the front side electrode 41 of the electricity extraction unit 4 is integrally formed with the front side electrode 31 of the adjacent thin film solar battery cell 3. The front side electrode 41 is an example of the “connecting section” in the present invention.

In the electricity extraction unit 4 (electricity extraction units 4a and 4b), a plurality of openings 44 in the form of holes are formed by removing the backside electrode 43 and the semiconductor layer 42 to expose the front side electrode 41. The plurality of openings 44 are placed along the Y direction with a predetermined spacing therebetween (approximately 30 mm in the present embodiment). Each opening 44 is formed in a square shape in the plan view, with a length of each side of approximately 4 mm.

In addition, a solder joint 5 joined to the exposed front side electrode 31 is provided in each opening 44. In other words, a plurality of solder joints 5 are formed in a dot shape along the Y direction with a predetermined spacing therebetween (approximately 30 mm in the present embodiment). In addition, in the plan view, the solder joint 5 is formed in a circular shape having a diameter of approximately 2 mm. That is, the solder joint 5 having a diameter of approximately 2 mm in the plan view is placed in the opening 44 having a square shape with the side of approximately 4 mm. Thus, the width of the opening 44 in the X direction (approximately 4 mm) is larger than the width of the solder joint 5 in the X direction (approximately 2 mm), and the width of the opening 44 in the Y direction (approximately 4 mm) is larger than the width of the solder joint 5 in the Y direction (approximately 2 mm). The solder joint 5 is placed at an approximate center of the opening 44. With this configuration, the outer peripheral surface of the solder joint 5 having a circular shape is provided to not contact (distanced from) the entire periphery of an inner side surface 44a of the opening 44 having the square shape. Unlike normal solder material (material of solder 8), the material of the solder joint 5 is a solder material (product name: Cerasolzer) which is easily joined to the front side electrode 41 (metal oxide). The solder joint 5 is joined at the front side electrode 41 using an ultrasound soldering iron. The solder joint 5 is an example of the “first fusing section” of the present invention.

The tab electrode 6 for extracting the electricity to the outside is provided extending in the Y direction and straddling over the plurality of openings 44, and the solder joint 5 provided in each of the plurality of openings 44 and the tab electrode 6 are joined. The tab electrode 6 has a structure in which a surface of a core line 6a made of Cu is covered (coated) by solder 6b, and is formed in a flat shape having a thickness of approximately 150 μm. The tab electrode 6 has a width in the X direction (approximately 2 mm in the present embodiment) which is smaller than the width of the opening 44 in the X direction. The solder joint 5 is placed so as to join the surface electrode 41 and the tab electrode 6 in a state where the solder joint 5 is not in contact with the entire periphery of the inner side surface 44a of the opening 44.

In the present embodiment, as shown in FIG. 2, a lower surface of the tab electrode 6 and the solder joint 5 are joined at a height position higher than the upper surface of the power generation unit (upper surface of backside electrode 43). At portions other than the junction portion between the tab electrode 6 and the solder joint 5, the lower surface of the tab electrode 6 is in contact with and supported by the upper surface of the backside electrode 43. In other words, the lower surface of the tab electrode 6 is positioned at a same height position as the upper surface of the power generation unit (upper surface of the backside electrode 43). Because of this, the upper surface of the tab electrode 6 at the junction portion between the tab electrode 6 and the solder joint 5 is higher than the upper surface of the tab electrode 6 in regions other than the junction portion. The tab electrode 6 is an example of the “extraction electrode” of the present invention.

The tab line 9 has a thickness of approximately 100 μm and a width of approximately 5 mm, and has a structure in which, similar to the tab electrode 6, a surface of a core line 9a made of Cu is covered (coated) with solder 9b. The tab line 9 is an example of the “extraction line” of the present invention. In addition, a lower surface of an end of the tab line 9 and an upper surface of the tab electrode 6 are joined by solder 8. In the present embodiment, the lower surface of the end of the tab line 9 and the upper surface of the tab electrode 6 are joined by the solder 8 at approximately the same position as one of the solder joints 5 in the plan view. With such a configuration, the solder 8 is positioned, in the plan view, at a position overlapping the solder joint 5 (junction portion between the solder joint 5 and the tab electrode 6). In other words, the solder 8 joins the tab electrode 6 and the tab line 9 at approximately the same position as the solder joint 5 joining the front side electrode 41 and the tab electrode 6. The solder 8 is an example of the “second fusing section” of the present invention.

The insulating tape 7 is provided to cover a part of the upper surface of the power generation unit (region corresponding to the tab line 9), in order to prevent electrical short-circuiting between the tab line 9 and the thin film solar battery cell 3 (power generation unit).

Next, a manufacturing process of the solar cell module 1 in the first preferred embodiment of the present invention will be described with reference to FIGS. 1-4.

First, the thin film solar battery cell 3 and the electricity extraction unit 4 are formed over the substrate 2.

Specifically, first, the front side electrode 31 and the front side electrode 41 made of tin oxide and having a thickness of approximately 800 nm are formed over an upper surface of the substrate 2 having an insulating surface through thermal CVD (Chemical Vapor Deposition).

Next, a fundamental wave of Nd:YAG laser having a wavelength of approximately 1064 nm, an oscillation frequency of approximately 20 kHz, and an average power of approximately 14.0 W is scanned from the side of the substrate 2 on the front side electrode 31, to form the groove section 31a.

Next, a p-type hydrogenated amorphous silicon carbide layer having a thickness of greater than or equal to approximately 10 nm and less than or equal to approximately 20 nm, an i-type hydrogenated amorphous silicon layer having a thickness of greater than or equal to approximately 250 nm and less than or equal to approximately 350 nm, and an n-type hydrogenated amorphous silicon layer having a thickness of greater than or equal to approximately 20 nm and less than or equal to approximately 30 nm are sequentially formed over the upper surface of the front side electrode 31 and the front side electrode 41 through plasma CVD, to form the photoelectric conversion unit 32 and the semiconductor layer 42 made of amorphous silicon-based semiconductor. A second harmonic of Nd:YAG laser having a wavelength of approximately 532 nm, an oscillation frequency of approximately 12 kHz, and an average power of approximately 230 mW is scanned from the side of the substrate 2 at a position adjacent to the groove section 31a, to form the groove section 32a.

Then, the back side electrodes 33 and 43 having a thickness of greater than or equal to approximately 200 nm and less than or equal to approximately 400 nm and made of a metal material having silver as a primary constituent are formed over the upper surfaces of the photoelectric conversion unit 32 and the semiconductor layer 42 through sputtering. In this process, in order to connect the plurality of thin film solar battery cells 3 in series, the backside electrode 33 is connected to the front side electrode 31 of the adjacent thin film solar battery cell 3 through the groove section 32a. Alternatively, it is also possible to form a layer of TCO (for example, ZnO or ITO) having a thickness of approximately 100 nm between the photoelectric conversion unit 32 and the backside electrode 33 and between the semiconductor layer 42 and the backside electrodes 43.

Next, a second harmonic of Nd:YAG laser having a wavelength of approximately 532 nm, an oscillation frequency of approximately 12 kHz, and an average power of 230 mW is scanned from the side of the substrate 2 at a position adjacent to the groove section 32a, to form the groove section 33a which separates the backside electrode 33 and the photoelectric conversion unit 32 (the backside electrode 43 and the semiconductor layer 42). With this process, the thin film solar battery cell 3 and the electricity extraction unit 4 are formed over the substrate 2.

Then, a second harmonic of Nd:YAG laser having a wavelength of approximately 532 nm, an oscillation frequency of approximately 12 kHz, and an average power of approximately 230 mW is scanned from the side of the substrate 2 on the electricity extraction unit 4, to form the plurality of openings 44.

Then, using an ultrasound soldering iron (not shown), the front side electrode 41 exposed by the opening 44, and the solder joint 5, are joined in the opening 44. As shown in FIGS. 1 and 2, the tab electrode 6 is then placed to straddle over the plurality of openings 44, and the solder joint 5 provided in the opening 44 is heated using a soldering iron (not shown) from above the tab electrode 6 to join the tab electrode 6 and the solder joint 5.

Next, as shown in FIG. 1, the insulating tape 7 is adhered to cover the region above the upper surface of the thin film solar battery cell 3 (power generation unit) (above the upper surface of the backside electrode 33). The ends of the pair of tab lines 9 are placed over the pair of tab electrodes 6 with the solder 8 therebetween. In the present embodiment, the end of the tab line 9 is placed at approximately the same position as the solder joint 5 in the plan view. As shown in FIGS. 1, 2, and 4, the solder 8 is heated using a soldering iron (not shown) from a side of the upper surface of the tab line 9, to join a predetermined site of the tab electrode 6 (approximate center position of solder joints 5 adjacent to each other in the plan view) and the end of the tab line 9 by the solder 8. Then, the thin film solar battery cell 3, electricity extraction unit 4, solder joint 5, tab electrode 6, insulating tape 7, solder 8, and a part of the tab line 9 are sealed by the sealing member made of EVA, and the back sheet 12 is adhered. In this process, the structure is formed such that the end of the tab line 9 is exposed from an opening formed in the back sheet 12. Finally, the terminal box 11 is connected to the end of the extended tab line 9, and the solar cell module 1 of the present embodiment is formed.

The solar cell module 1 in the present embodiment allows for the following advantages.

(1) The tab electrode 6 and the tab line 9 are joined by the solder 8 at a position overlapping the solder joint 5 in the plan view. More specifically, the front side electrode 41 and the tab electrode 6 are connected by the solder joint 5, and the tab electrode 6 and the tab line 9 are connected by the solder 8. With this configuration, the front side electrode 41, the tab electrode 6, and the tab line 9 can be made conductive in an approximate straight line in the direction of layering, and can be connected in a more advantageous manner. Therefore, it is possible to inhibit the increase in connection resistance between the front side electrode 41 and the tab electrode 6, and between the tab electrode 6 and the tab line 9, and consequently, the reduction of the output of the solar cell module 1 can be inhibited.

(2) The solder joint 5 and the solder 8 are connected at an overlapping position in the plan view. In other words, the tab electrode 6 and the tab line 9 are joined by the solder 8 at a position overlapping the solder joint 5. With this configuration, in a portion which overlaps the solder 8, intrusion of the sealing member 13 into a region between the electricity extraction unit 4 and the tab electrode 6 during the sealing step can be prevented. Therefore, in the solar cell module 1 of the present embodiment, stress between the electricity extraction unit 4 and the tab electrode 6 caused by expansion and contraction, due to exposure to a thermal cycle, of the sealing member 13 intruding between the electricity extraction unit 4 and the tab electrode 6 at the portion overlapping the solder 8 can be prevented and reduced. With this configuration, it is possible to prevent detachment of the tab electrode 6 from the electricity extraction unit 4 at the portion overlapping the solder 8, and to prevent consequent increase in the connection resistance and reduction in output of the solar cell module 1. In other words, even when the structure is exposed to the thermal cycle, the electricity can be made to conduct through the electricity extraction unit 4, the tab electrode 6, and the tab line 9 in an approximate straight line in the direction of layering, and the reliability can be improved.

(3) Because the solder joint 5 is joined at the lower surface of the tab electrode 6 and the lower surface of the tab line 9 is joined to the upper surface of the tab electrode 6 by the solder 8, the tab line 9 can be easily joined to the tab electrode 6.

(4) A plurality of solder joints 5 for joining the front side electrode 41 and the tab electrode 6 are provided in a dot shape with a predetermined spacing therebetween. With this configuration, because certain portions of the front side electrode 41 and the tab electrode 6 are not joined, the stress applied between the front side electrode 41 and the tab electrode 6 can be reduced, and the detachment of the front side electrode 41 and the tab electrode 6 can be prevented.

(5) The solder joint 5 for joining the front side electrode 41 and the tab electrode 6 is provided not in contact with the inner side surface 44a of the opening 44 of the electricity extraction unit 4. With this configuration, even when detachment occurs at an interface between the front side electrode 41 of the electricity extraction unit 4 and the semiconductor layer 42 or at an interface between the semiconductor layer 42 and the backside electrode 43, the detachment force is not applied to the solder joint 5. With this configuration, the occurrence of the detachment at the interface between the front side electrode 41 and the solder joint 5 can be inhibited, and consequently, reduction in reliability of the solar cell module 1 can be inhibited.

(6) A plurality of openings 44 are formed in the electricity extraction unit 4 with a predetermined spacing therebetween along the Y direction which is a direction of extension of the tab electrode 6, and the front side electrode 41 and the tab electrode 6 are joined by the solder joint 5 at a plurality of locations through each of the plurality of openings 44. With this configuration, portions other than the opening 44, and forming the electricity extraction unit 4 (the semiconductor layer 42 and the backside electrode 43), are placed in a region between the locations of junction (openings 44) between the tab electrode 6 and the front side electrode 41. Because of this, in the region between the locations of junction (openings 44) between the tab electrode 6 and the front side electrode 41, the tab electrode 6 can be supported from below by the portions other than the opening 44 and forming the electricity extraction unit 4 (the semiconductor layer 42 and the backside electrode 43). By supporting the tab electrode 6 from below at regions other than the junction location, even when a force in a direction of pressing the tab electrode 6 downward is applied from the outside, the force can be tolerated from below. Thus, it is possible to inhibit concentrated application of the force at the junction location. Therefore, the force applied to the tab electrode 6 and the solder joint 5 at the junction location can be reduced, and the occurrence of detachment at the interface between the front side electrode 41 and the solder joint 5 can be inhibited. As a result, reduction in reliability of the solar cell module 1 can be inhibited.

For example, in the above-described preferred embodiment, an exemplary configuration is shown in which the tab electrode 6 and the tab line 9 are joined by the solder 8 at approximately the center position of adjacent solder joints 5, but the present invention is not limited to such a configuration, and the tab electrode 6 and the tab line 9 may be joined by the solder 8 at a deviated position such that the solder 8 is not overlapped with the solder joint 5 in the plan view.

In addition, in the above-described preferred embodiment, an example configuration is shown in which the solder 8 is placed at a position deviated in a direction of extension of the tab electrode 6 (Y direction) with respect to the solder joint 5 in the plan view, but the present invention is not limited to such a configuration, and the solder 8 may be placed at a position deviated in the X direction from the solder joint 5 in the plan view.

Moreover, in the above-described preferred embodiment, an exemplary configuration is shown in which the front side electrode 41 and the tab electrode 6 are joined by the solder joints 5 placed in a plurality of dot shapes, but the present invention is not limited to such a configuration, and the front side electrode 41 and the tab electrode 6 may be joined by placing, with a predetermined spacing therebetween, the solder joints (first fusing section) placed in a line shape extending in the Y direction. When a plurality of the line-shaped solder joints (first fusing section) are provided with a predetermined spacing therebetween, the tab electrode 6 and the tab line 9 may be joined by the solder (second fusing section) such that the solder (first fusing section) is overlapped, at the region in the plan view between the solders (first fusing section).

Furthermore, in the above-described preferred embodiment, an exemplary configuration is shown in which the tab electrode 6 and the tab line 9 are joined by heating with a soldering iron in a state where the solder 8 is sandwiched by the tab electrode 6 and the tab line 9, but the present invention is not limited to such a configuration, and the tab electrode 6 and the tab line 9 may be joined with a coating solder 6b of the tab electrode 6 and a coating solder 9b of the tab line 9, without the use of the solder 8. In this case, the coating solder 6b and the coating solder 9b fused at the junction portion is an example of the “second fusing section” of the present invention.

In addition, in the above-described preferred embodiment, an exemplary configuration is shown in which the solder joint 5 and the solder 8 are used as the “first fusing section” and the “second fusing section” of the present invention, respectively, but the present invention is not limited to such a configuration, and a fusing member other than the solder may be used as the “first fusing section” and the “second fusing section” of the present invention.

Moreover, in the above-described preferred embodiment, an example configuration is shown where the opening 44 is formed in a square shape, but the present invention is not limited to such a configuration, and the opening 44 may be of other shapes such as circle, ellipse, and rectangle.

### Second Preferred Embodiment

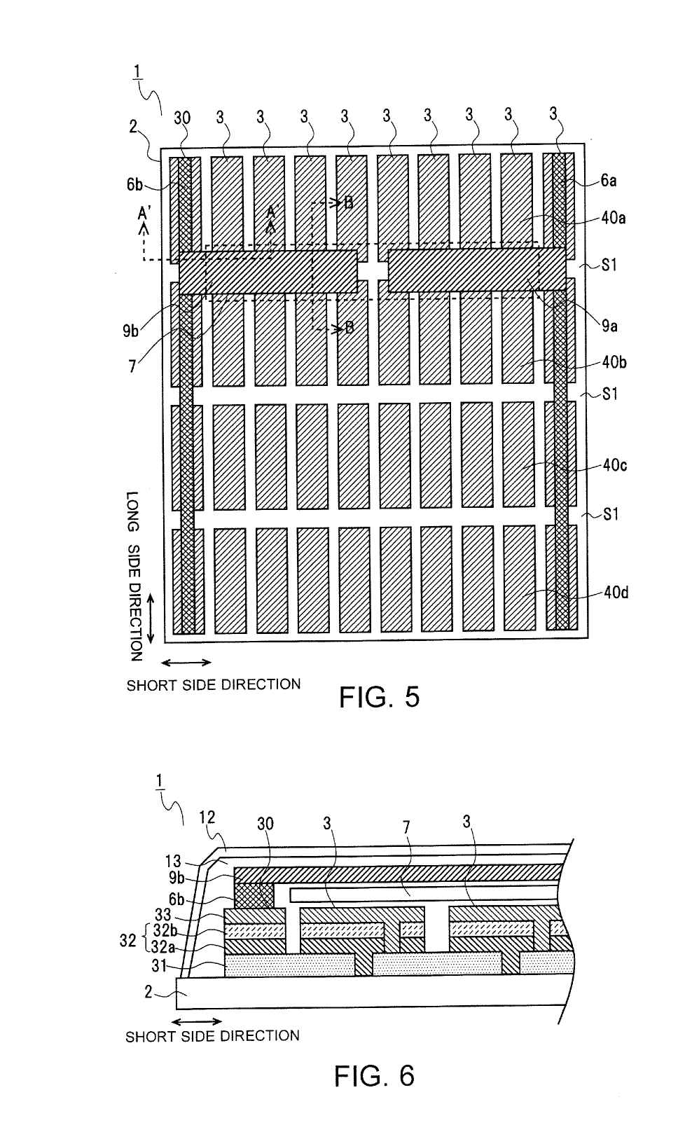

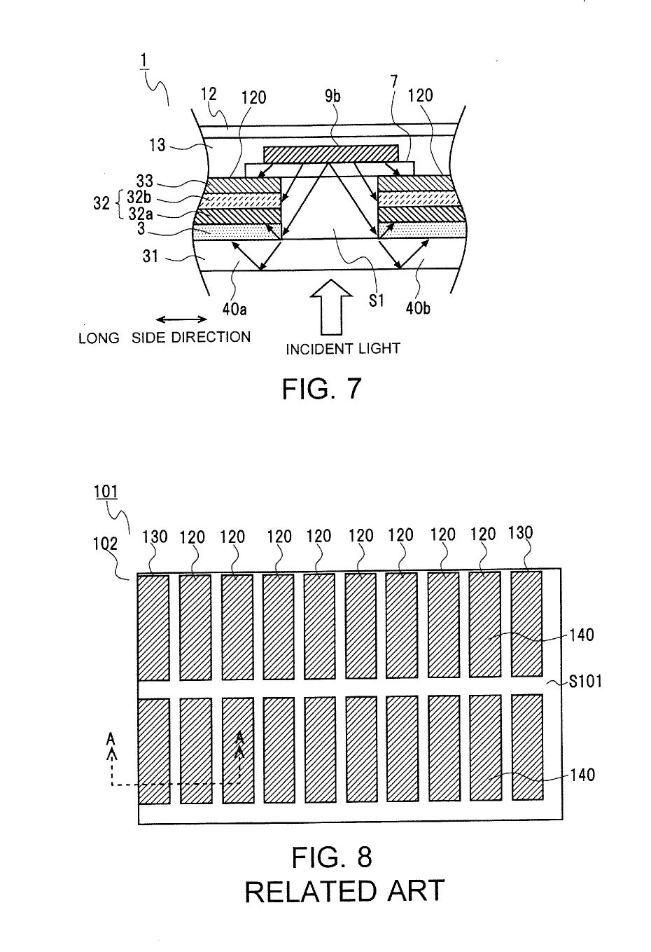

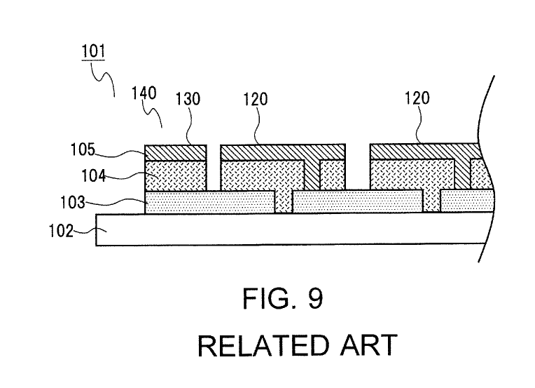

A second preferred embodiment of the present invention will now be described with reference to the drawings. FIG. 5 shows a top view of a solar cell module 1 according to a second preferred embodiment of the present invention. In the following description, the solar cell module 1 according to the second preferred embodiment of the present invention will be described with reference to FIG. 5, FIG. 6 which shows a cross sectional diagram of the solar cell module shown in FIG. 5 along an A′-A′ cross section, and FIG. 7 which shows a cross sectional diagram along a B-B cross section.

In the solar cell module 1 manufactured in the present embodiment, a plurality of thin film solar battery cells 3 are placed over a substrate 2. Each thin film solar battery cell 3 is formed by sequentially layering a front side electrode 31, photoelectric conversion units 32a and 32b, and a backside electrode 33 over the substrate 2. The thin film solar battery cell 3 is electrically separated by a slit S1 extending in a short side direction so that the thin film solar battery cells are divided into groups of thin film solar battery cells 40a, 40b, 40c, and 40d along the long side (longitudinal) direction.

In the present embodiment, the front side electrode 31 is formed in a strip shape extending in the long side direction in the plan view.

The photoelectric conversion units 32a and 32b are formed in a strip shape extending in the long side direction over the front side electrode 31. In the present embodiment, the photoelectric conversion units 32a and 32b are formed with an amorphous silicon semiconductor and a microcrystalline silicon semiconductor, respectively. In the present embodiment, the term “microcrystalline” is used to mean not only a complete crystalline state, but also a partially amorphous state.

In addition, in the present embodiment, the backside electrode 33 is formed over the photoelectric conversion unit 32b.

The thin film solar battery cell 3 is constructed with the front side electrode 31, photoelectric conversion units 32a and 32b, and backside electrode 33 formed in a manner as described above. The front side electrode 31 and the backside electrode 33 of adjacent thin film solar battery cells 3 are connected such that the adjacent thin film solar battery cells 3 are electrically connected in series. Alternatively, a layer made of a transparent conductive material may be interposed between the backside electrode 33 and the photoelectric conversion unit 32b.

As described above, the thin film solar battery cells 3 are divided into groups of thin film solar battery cells 40a˜40d by slits S1 formed by removing the photoelectric conversion units 32a and 32b and the backside electrode 33.

In the present embodiment, the term “short side direction” refers to a direction where the solar cell modules 1 are connected in series, and the term “long side direction” refers to a direction approximately perpendicular to the direction in which the solar cell modules 1 are electrically connected in series.

As shown in FIG. 5, a bus region 30 is formed in the thin film solar battery cells 3 positioned at both ends in the short side direction of each of the groups of thin film solar battery cells 40a˜40d. Tab electrodes 6a and 6b made of solder coated copper film are placed straddling over the plurality of bus regions 30 provided for each of the groups of thin film solar battery cells 40a˜40d. With the tab electrodes 6a and 6b, the groups of thin film solar battery cells 40a˜40d are connected in parallel, and electric power generated by the plurality of thin film solar battery cells 3 of each of the groups of thin film solar battery cells 40a˜40d can be extracted. For the solder coated copper film used for the tab electrodes 6a and 6b, a structure having a thickness of the copper film which is the base member of approximately 40 μm˜120 μm is used, and preferably, a structure having a thickness of approximately 80 μm is used.

As shown in FIGS. 5 and 7, an insulating tape 7 is placed covering over the slit S1 positioned between the tab electrodes 6a and 6b and over ends of groups of thin film solar battery cells 40a and 40b adjacent to the slit S1. The insulating tape 7 is made of PET having a light transmissive characteristic, and the thickness of the insulating tape 7 is preferably 40 μm˜120 μm which is approximately the same as the thicknesses of the tab electrode 6a and 6b and the solder (not shown) for fixing the tab electrodes 6a and 6b, and is in particular in a range of 40 μm˜80 μm.

Tab lines 9a and 9b are connected to the tab electrodes 6a and 6b, respectively. The tab lines 9a and 9b are made of solder coated copper films having a reflective surface, and are placed covering the slits S1. The insulating tape 7 is placed between the tab lines 9a and 9b and adjacent groups of thin film solar battery cells 40a and 40b, to prevent short-circuiting between the tab lines 9a and 9b and the group of thin film solar battery cells 40.

In this configuration, with the tab lines 9a and 9b having the reflective surface, it is possible to more efficiently reflect and scatter light incident between the photoelectric conversion layers 40a and 40b. With the reflected and scattered light being incident into the thin film solar battery cell 3, as will be described below, the amount of power generation of the thin film solar battery cell 3 can be increased.

A sealing member 13 made of EVA (ethylene vinyl acetate) or the like for sealing the plurality of formed thin film solar battery cells 3, and a back sheet 12 made of PET/Al film/PET or the like are provided over the substrate 2. One end, of each of the tab lines 9a and 9b, which is not connected to each of the tab electrodes 6a and 6b extends from an opening formed in the sealing member 13 and the back sheet 12, connected to a terminal box (not shown), and the solar cell module 1 is completed.

In the present embodiment, photoelectric conversion units 32a and 32b in which the amorphous silicon semiconductor and the microcrystalline silicon semiconductor are sequentially layered are used, but alternatively, similar advantages may be obtained by a single layer structure of a microcrystalline or amorphous photoelectric conversion unit or a layered structure of three or more layers of the microcrystalline or amorphous photoelectric conversion units.

Alternatively, an intermediate layer made of ZnO, SnO₂, SiO₂, or MgZnO may be provided between the first photoelectric conversion unit and the second photoelectric conversion unit, to achieve a structure with an improved optical characteristic.

The tab electrodes 6a and 6b are not limited to being at the end of the substrate 2, and may alternatively be provided near the center of the substrate 2.

The present invention is not limited to a structure in which the insulating tape 7 and the tab lines 9a and 9b are placed between the groups of thin film solar battery cells 40a and 40b, and alternatively, a structure may be employed in which the insulating tape 7 and the tab lines 9a and 9b are placed on a spacing formed between adjacent groups of thin film solar battery cells.

Alternatively, as the back sheet 12, a structure in which a metal film is sandwiched by a fluorine-based resin (ETFE, PVDF, PCTFE, etc.), PC, glass, or the like, SUS, or a steel plate may be employed. For a surface of the back sheet 12 opposing the thin film solar battery cell 3, a structure having a white-based color is preferably used. With such a configuration, the light incident from between the adjacent photoelectric conversion layers 20 can be more efficiently scattered. By the scattered light being incident on the thin film solar battery cell 3, it is possible to increase the amount of power generation of the thin film solar battery cell 3. In addition, the back sheet 12 and an insulating adhesion member 7 preferably have similar colors. With this configuration, the color tone of the portion of the solar cell module 1 which can be seen between the thin film solar battery cells 3 when the solar cell module 1 is viewed from the side of the substrate 2 can be set unified, and the design of the solar cell module 1 can be improved.

At the end of the solar cell module 1, an aluminum frame may be attached with a butyl rubber or the like.

An overlapping portion between the slit S1 and the tab lines 9a and 9b which is a characteristic of the present embodiment will now be described in detail with reference to FIGS. 6 and 7.

For the tab lines 9a and 9b, a structure is used having conductivity, having a reflective surface at least on a surface opposing the groups of thin film solar battery cells 40a and 40b, and having a width wider than a width of the slit S1 which divides the adjacent groups of thin film solar battery cells 40a and 40b. The tab line 9b is placed over the slit S1 covering both ends of the groups of thin film solar battery cells 40a and 40b. With this configuration, the light incident on the slit S1 is transmitted through the insulating tape 7 and is incident on the reflective surface of the tab line 9b. The light incident on the reflective surface of the tab line 9b is reflected and scattered, and is incident directly on the photoelectric conversion units 32a and 32b, or is reflected and scattered at the interface between the front side electrode 31 and the substrate 2 or the interface between the substrate 2 and the outside environment, and is again incident to the photoelectric conversion units 32a and 32b. In other words, the light incident in the slit S1 between the groups of thin film solar battery cells 40 which in the related art cannot be used for contribution of photoelectric conversion can be again made to enter the thin film solar battery cell 3, and the output of the solar cell module 1 can be improved.

In the present embodiment, as shown in FIG. 7, the insulating tape 7 is placed between the tab line 9b and the slit S1 which divides the adjacent groups of thin film solar battery cells 40a and 40b. With the insulating tape 7, it is possible to prevent short-circuiting between the tab line 9b and the groups of thin film solar battery cells 40a and 40b, more specifically, between the tab line 9b and the backside electrode 33 of the thin film solar battery cell 3 which is a part of the thin film solar battery cells 40a and 40b.

In addition, for the insulating tape 7, a light transmissive member is used. Because of this, the light incident to the slit S1 is transmitted through the insulating tape 7, incident on the reflective surfaces of the tab lines 9a and 9b, and is again incident to the photoelectric conversion units 32a and 32b. In this manner, in the present embodiment, the amount of light incident in the thin film solar battery cell 3 can be increased, and a larger amount of light can be contributed to the photoelectric conversion. Consequently, the output of the solar cell module 1 can be improved.

For the insulating tape 7, a thin member having a thickness of approximately 40 μm˜80 μm may be used, to reduce the distance between the thin film solar battery cell 3 and the tab line 9b, and therefore reduce the light scattered and reflected to the backside electrode 33 which does not contribute to photoelectric conversion. With this configuration, more incident light incident from the side of the substrate 2 to the slit S1 can be made to enter the thin film solar battery cell 3 and contribute to the photoelectric conversion, resulting in an improvement in the output of the solar cell module 1.

The preferred embodiments described above are merely exemplary and should not be considered as limiting. The scope of the invention is defined by the claims and not by the description of the above-described preferred embodiments, and includes all equivalences of the claims and modifications within the scope of the claims.

What is claimed is:

1. A solar cell module comprising:
a substrate;
a power generation unit comprising a plurality of thin film solar battery cells having a front side electrode formed over the substrate, a photoelectric conversion layer formed over the front side electrode, and a backside electrode formed over the photoelectric conversion layer;
an electricity extraction unit comprising a connecting section connected to a thin film solar battery cell positioned at an end of the power generation unit;
an extraction electrode formed over the electricity extraction unit and configured to extract electricity generated by the power generation unit;
a first fusing section which joins the connecting section and the extraction electrode; and
an extraction line provided to extract electricity from the extraction electrode and joined to the extraction electrode by a second fusing section at a position overlapping the first fusing section in a plan view.

2. The solar cell module according to claim 1, wherein
in the electricity extraction unit, a plurality of the first fusing sections are provided to join the connecting section and the extraction electrode at a plurality of locations along a direction of extension of the extraction electrode with a predetermined spacing therebetween, and
the extraction electrode and the extraction line are joined over first fusing section in the plan view.

3. The solar cell module according to claim 1, wherein
the first fusing section is joined to a lower surface of the extraction electrode, and
an upper surface of the extraction electrode and a lower surface of the extraction line are joined by the second fusing section.

4. The solar cell module according to claim 1, wherein
an opening formed to expose the connecting section is formed in the electricity extraction unit, and
the first fusing section is provided distanced from an inner side surface of the opening, and joins the connecting section and the extraction electrode through the opening.

5. A solar cell module comprising:
a substrate which is light transmissive;
a plurality of thin film solar battery cells provided over the substrate and connected to each other in a first direction;
an extraction electrode placed over a first surface of the plurality of thin film solar battery cells and configured to collect electric power; and
an extraction line connected to the extraction electrode over the first surface of the thin film solar battery cell and configured to extract the electric power from the extraction electrode to the outside, wherein
the plurality of thin film solar battery cells are divided by a slit extending in a second direction crossing the first direction, and the extraction electrode is placed to overlap the slit.

6. The solar cell module according to claim 5, wherein
an insulating member which is light transmissive is interposed between the extraction line and the slit.
